(19) United States
(12) Patent Application Publication
(10) Pub. No.: US 2025/0267788 A1
(43) Pub. Date: Aug. 21, 2025

(54) GLASS CORE LAMINATE, GLASS CORE LAMINATE MANUFACTURING METHOD, AND GLASS CORE LAMINATE CUTTING METHOD

(71) Applicant: JOONGWOO M-TECH CO., LTD, Ansan-si (KR)

(72) Inventor: Sung Soo Park, Yongin-si (KR)

(21) Appl. No.: 18/648,598

(22) Filed: Apr. 29, 2024

(30) Foreign Application Priority Data
Feb. 21, 2024 (KR) 10-2024-0024809

(51) Int. Cl. H05K 1/03; B32B 3/30; B32B 38/10

(52) U.S. Cl. CPC H05K 1/0306; B32B 3/30; B32B 38/10; B32B 2250/03; B32B 2250/40; B32B 2307/206; B32B 2457/08

(57) ABSTRACT

Proposed are a glass core laminate, a method for manufacturing a glass core laminate, and a method for cutting a glass core laminate, wherein the occurrence of physical damage such as chipping and cracks that occur in a cutting area during a singulation process is suppressed, thereby enhancing the yield of a singulated package unit and product reliability. The glass core laminate includes a glass layer and an insulating layer laminated on the upper and lower surfaces of the glass layer. At this time, the glass layer has cutting grooves defined in advance along a singulation cutting line before the insulating layer is laminated on the upper and lower surfaces.

### CROSS-REFERENCE TO RELATED APPLICATION(S)

This application claims priority to Korean Patent Application No. 10-2024-0024809, filed on Feb. 21, 2024, the entire disclosure of which is incorporated herein for all aspects.

### BACKGROUND

### 1) Field

The disclosure relates to a glass core laminate, a method for manufacturing a glass core laminate, and a method for cutting a glass core laminate and, specifically, to a glass core laminate, a method for manufacturing a glass core laminate, and a method for cutting a glass core laminate, wherein the occurrence of physical damage such as chipping and cracks that occur in a cutting area during a singulation process is suppressed, thereby enhancing the yield of a singulated package unit and product reliability.

### 2) Description of Related Art

In response to the demand for miniaturization of semiconductor packaging substrates, there is a high-density, high-performance 2.5D packaging technology using an intermediate substrate, the so-called interposer, to overcome the limitations of existing organic substrates. 2.5D packaging is attracting attention as an advanced packaging technology that integrates multiple semiconductor individual chips into a single package by horizontal connection. However, unlike existing substrate processes, 2.5D packaging uses a semiconductor process, and thus the entry barrier is high, the manufacturing process is complicated, and significant costs are consumed.

Therefore, as an alternative to implement more high-performance semiconductors, much focus is on and research are being conducted on the use of glass substrates, so-called glass core substrates (GCS) or glass interposers, rather than existing organic substrates.

However, since a glass material used in a glass core substrate or glass intermediate substrate is a brittle material that is easily broken, the glass materials affects the durability of semiconductor packages that require high reliability. In particular, defect-free processing and high durability of cut packaging units are required in a singulation process of cutting glass substrates to packaging size.

FIG. 1 is a cross-sectional and plan exemplary view showing a conventional glass core laminate, and FIGS. 2A and 2B are each an exemplary view for explaining a singulation process for a conventional glass core laminate.

A glass core laminate basically includes a glass layer 1 made of glass having a via hole, that is, a through-hole 11 for connection between conductors, and an insulating layer 2 laminated on a surface of the glass layer 1. In addition, a chip may be mounted on an outer surface of the insulating layer 2.

Once a glass core laminate is prepared, a singulation process is performed, that is, a plurality of packaging units are cut and separated by irradiating a laser beam L along a preset singulation cutting line CL or using a mechanical cutter such as a wheel.

However, unlike substrates that use an epoxy-based resin material as a core, a substrate 1 that uses glass as a core experiences physical damage such as chipping and cracks in a cutting area during a singulation process, and the damage caused increase the risk of breakdown, and thus there is a problem that the yield of a packaging unit and the reliability of a product are greatly reduced.

Of course, in order to compensate for physical damage caused during a singulation process, it may be considered to perform physical and chemical post-processing processes such as grinding and resin coating on an edge surface of a glass layer 1.

However, during a post-processing process, insulating layers 2 are laminated in several layers in advance on the upper and lower surfaces of a glass layer 1, and thus moisture or chemical damage may be directly transferred to the insulating layers 2 in a post-processing procedure such as grinding or resin coating. Therefore, there are many practical difficulties in a singulation process for a glass core laminate made of glass.

### Related Art

### Patent Document

(Patent Document 1) Republic of Korea Patent Publication No. 2011-0134703 (published on Dec. 15, 2011)

### SUMMARY

The disclosure provides a glass core laminate, a method for manufacturing a glass core laminate, and a method for cutting a glass core laminate, wherein the occurrence of physical damage such as chipping and cracks that occur in a cutting area during a singulation process is suppressed, thereby greatly enhancing the yield of a singulated package unit and product reliability.

The aspect of the disclosure is not limited to that mentioned above, and other aspects not mentioned will be clearly understood by those skilled in the art from the description below.

According to an embodiment, a glass core laminate includes: a glass layer; and an insulating layer laminated on the upper and lower surfaces of the glass layer, wherein the glass layer has cutting grooves defined in advance along a singulation cutting line before the insulating layer is laminated on the upper and lower surfaces.

The cutting grooves may be defined as a transformable portion extending in the thickness direction of the glass layer is defined by irradiating a laser beam to the glass layer and as the transformable portion is etched by immersing the glass layer on which the transformable portion is defined in an etching solution.

The glass layer may further have a through-hole for electrical connection between layers of the glass core laminate, and the through-hole may be defined as a transformable portion extending in the thickness direction of the glass layer is defined by irradiating a laser beam to the glass layer and as the transformable portion is etched by immersing the glass layer on which the transformable portion is defined in an etching solution. The cutting grooves may be defined together when the through-hole is defined.

The through-hole and the cutting grooves may be defined together as at least one of the followings is set differently: power of the laser beam for defining the through-hole and the cutting groove, respectively; a focusing position of the laser beam for defining the through-hole and the cutting groove, respectively; and an etching time for defining the through-hole and the cutting groove, respectively.

The singulation cutting line may include: a plurality of first cutting lines that, to define a horizontal side of a package unit, extend in the horizontal direction and are spaced apart by the vertical width of the package unit; and a plurality of second cutting lines that, to define a vertical side of the package unit, extend in the vertical direction and are spaced apart by the horizontal width of the package unit. Starting and ending points of each of the first cutting line and the second cutting line may be disposed away from an edge side surface of the glass layer without extending to the edge side surface of the glass layer.

The singulation cutting line may include a plurality of unit cutting lines prepared to correspond to the shape of a package unit and spaced apart at predetermined intervals in the horizontal and vertical directions of the package unit.

The unit cutting lines may have a curved corner area.

According to another embodiment, a method for manufacturing a glass core laminate includes: a glass layer preparation step of preparing a glass layer; and an insulating layer preparation step of laminating an insulating layer on the upper and lower surfaces of the glass layer, wherein in the glass layer preparation step, the glass layer has cutting grooves defined along a singulation cutting line on the upper and lower surfaces.

In the glass layer preparation step, the cutting grooves may be defined as a transformable portion extending in the thickness direction of the glass layer is defined by irradiating a laser beam to the glass layer and as the transformable portion is etched by immersing the glass layer on which the transformable portion is defined in an etching solution.

In the glass layer preparation step, the glass layer may further have a through-hole for electrical connection between layers of the glass core laminate, and the through-hole may be defined as a transformable portion extending in the thickness direction of the glass layer is defined by irradiating a laser beam to the glass layer and as the transformable portion is etched by immersing the glass layer on which the transformable portion is defined in an etching solution. The cutting grooves may be defined together when the through-hole is defined.

In the glass layer preparation step, the through-hole and the cutting grooves may be defined together as at least one of the followings is set differently: power of the laser beam for defining the through-hole and the cutting groove, respectively; a focusing position of the laser beam for defining the through-hole and the cutting groove, respectively; and an etching time for defining the through-hole and the cutting groove, respectively.

The power of the laser beam irradiated to define the cutting grooves may be smaller than the power of the laser beam irradiated to define the through-hole.

In the glass layer preparation step, the through-hole and the cutting grooves may be defined together by: defining a first transformable portion extending in the thickness direction of the glass layer by irradiating a first laser beam to the glass layer; etching a portion of the first transformable portion by immersing the glass layer on which the first transformable portion is defined in an etching solution for a first etching time; separating the glass layer from the etching solution, and irradiating the glass layer with a second laser beam to define a second transformable portion extending in the thickness direction of the glass layer; and immersing the glass layer on which the second transformable portion is defined in an etching solution for a second etching time to etch the remaining portion of the first transformable portion and simultaneously etch the second transformable portion.

The method for manufacturing a glass core laminate may further include, prior to the insulating layer preparation step, a conductive material filling and patterning step of filling and patterning the through-hole with a conductive material.

According to a still another embodiment, a method for cutting a glass core laminate includes: a laminate manufacturing step of manufacturing a glass core laminate; a partial cutting step of removing a portion of an insulating layer by irradiating a laser beam to the insulating layer so that cutting grooves are exposed on a surface of the glass core laminate; and a unit separation step of separating a package unit from the glass core laminate by irradiating a laser beam or applying a physical external force to a glass layer so that the remaining area of a singulation cutting line where the cutting grooves are not defined is broken.

According to the disclosure, cutting grooves defined along a singulation cutting line is defined in advance in a glass layer, so that during a singulation process, it is possible to suppress the occurrence of physical damage such as chipping and cracks in a cutting area. Accordingly, it is possible to greatly enhance the yield of packaging units and the reliability of a product.

The effects of the disclosure are not limited to the effects described above, and should be understood to include all effects that are inferable from the configuration of the disclosure described in the detailed description or claims of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional and plan exemplary view showing a conventional glass core laminate;

FIGS. 2A and 2B are each an exemplary view for explaining a singulation process for a conventional glass core laminate;

FIG. 3 is a cross-sectional exemplary view showing a glass core laminate according to an embodiment;

FIG. 4 is a cross-sectional exemplary view showing a glass layer of FIG. 3;

FIGS. 5A, 5B, and 5C are each an exemplary view for explaining a procedure of defining cutting grooves in a glass layer according to an embodiment;

FIGS. 6A, 6B, and 6C are each an exemplary view for explaining a procedure of defining cutting grooves in a glass layer according to another embodiment;

FIG. 7 is a block flow diagram showing a method for manufacturing a glass core laminate according to an embodiment;

FIGS. 8A, 8B, 8C, and 8D are each an exemplary view for showing a method for manufacturing a glass core laminate according to an embodiment;

FIGS. 9A and 9B are each a plan view of a glass core laminate for explaining a pattern of a singulation cutting line according to an embodiment;

FIG. 10 is a block flow diagram showing a method for cutting a glass core laminate according to an embodiment; and

FIGS. 11A, 11B, 11C, and 11D are each an exemplary view showing a method for cutting a glass core laminate according to an embodiment.

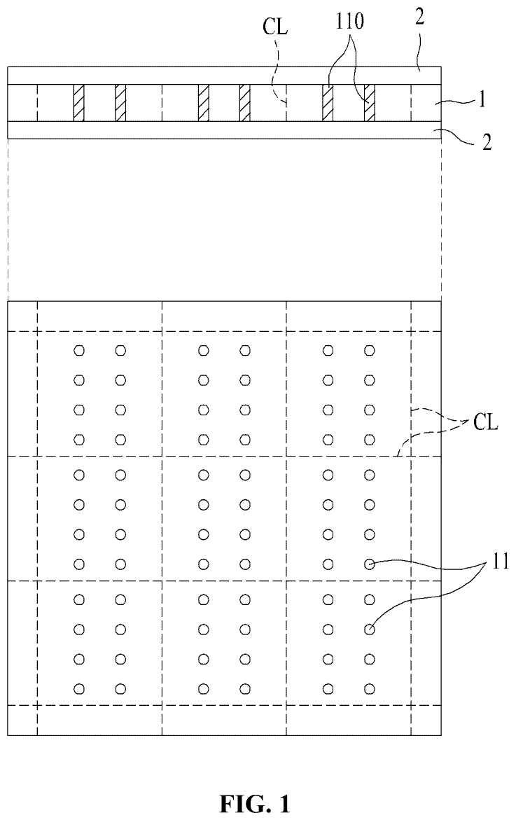

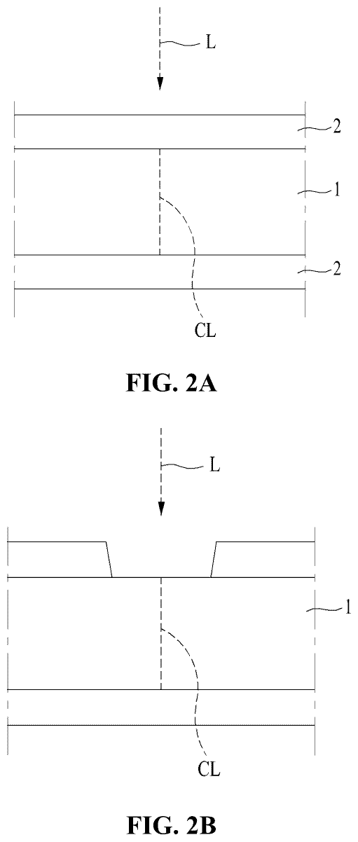

### DETAILED DESCRIPTION

Hereinafter, the disclosure will be described with reference to the accompanying drawings. However, the disclosure may be implemented in various different forms and, therefore, is not limited to the embodiments described herein. In order to clearly explain the disclosure in the drawings, portions unrelated to the description are omitted, and similar portions are given similar reference numerals throughout the specification.

Throughout the specification, when a portion is said to be “connected (linked, contacted, combined)” with another portion, this includes not only a case of being “directly connected” but also a case of being “indirectly connected” with another member in between. In addition, when a portion is said to “include” a certain component, this does not mean that other components are excluded, but that other components may be added, unless specifically stated to the contrary.

The terms used herein are merely used to describe specific embodiments and are not intended to limit the disclosure. Singular expressions include plural expressions unless the context clearly dictates otherwise. In this specification, it should be understood terms such as “include” or “have” are to designate the presence of features, numbers, steps, operations, components, parts, or combinations thereof described in the specification, but are not to exclude in advance the possibility of the presence or addition of one or more other features, numbers, steps, operations, components, parts, or combinations thereof.

Hereinafter, embodiments of the disclosure will be described in detail with reference to the accompanying drawings.

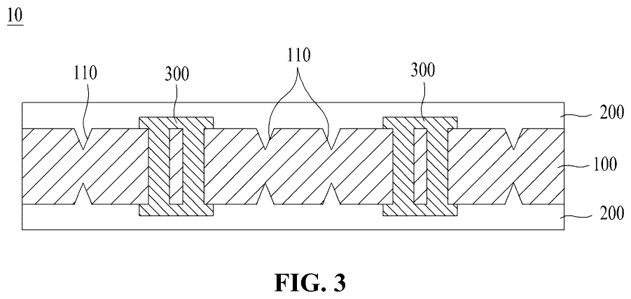

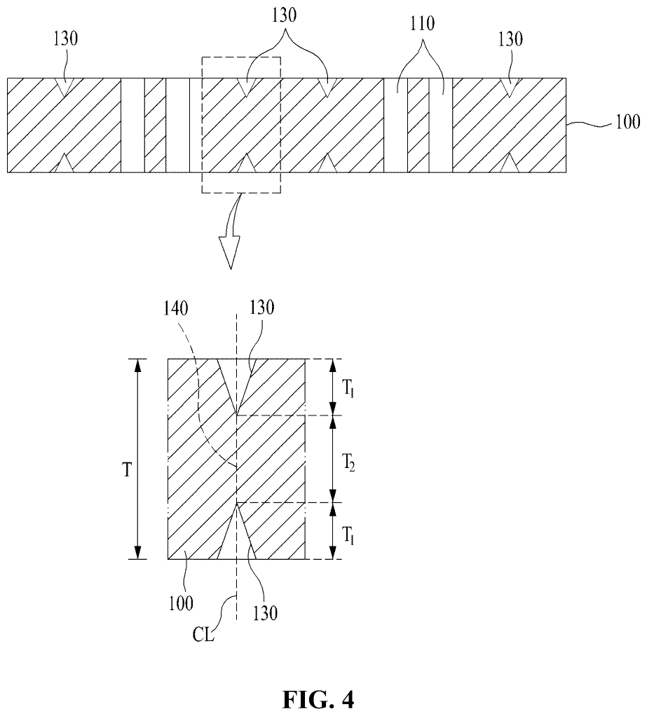

FIG. 3 is a cross-sectional exemplary view showing a glass core laminate according to an embodiment, and FIG. 4 is a cross-sectional exemplary view showing a glass layer of FIG. 3. Referring to FIGS. 3 and 4, a glass core laminate 10 according to this embodiment may include a glass layer 100, a conductive material 300, and an insulating layer 200.

The glass layer 100 corresponds to a core substrate and may be made of glass.

The glass layer 100 may have a through-hole 110 for electrical connection between layers of the glass core laminate 10. The through-hole 110 may be defined through the upper and lower surfaces of the glass layer 100. The through-hole 110 may be filled with the conductive material 300.

The glass layer 100 may have cutting grooves 130.

The cutting grooves 130 may be defined on the upper and lower surfaces of the glass layer 100 on which the insulating layer 200 is laminated, and may be defined along a singulation cutting line CL.

The cutting grooves 130 may be defined continuously along the singulation cutting line CL, or may be defined in the form of a discontinuous stitch.

The cutting grooves 130 may be prepared as a pair on the upper and lower surfaces of the glass layer 100 symmetrically with respect to the center line in the thickness direction of the glass layer 100. The pair of cutting grooves 130 may have the same depth in the thickness direction of the glass layer 100, or may have different depths.

When the thickness of the glass layer 100 is T, a depth T1 of the cutting grooves 130 may have a depth less than half (T/2) of the thickness T of the glass layer 100. Accordingly, the remaining area in the thickness direction of the glass layer 100 where the cutting grooves 130 are defined may be connected through an extension portion 140. Preferably, a total depth T1*2 of the pair of cutting grooves 130 may have a depth less than half T/2 of the thickness T of the glass layer 100.

To elaborate, the depth T1 of the cutting grooves 130 and a thickness T2 of the extension portion 140 may be set appropriately within a range such that the singulation cutting line CL is easily broken by a laser beam or physical external force during a singulation process. At the same time, the depth T1 of the cutting grooves 130 and the thickness T2 of the extension portion 140 may be set appropriately within a range such that, in a procedure of handling the glass core laminate 10 before a singulation process, breakdown does not occur and stable support of the glass core laminate 10 is guaranteed. In addition, the depth T1 of the cutting grooves 130 and the thickness T2 of the extension portion 140 may be adjusted and set according to various variables such as the thickness T and material of the glass layer 100.

The conductive material 300 may be filled into the through-hole 110.

The conductive material 300 may be a conductive material such as Cu, and may be filled into the through-hole 110 via a plating process. Through this conductive material 300, electrical connection between layers of the glass core laminate 10 becomes possible.

The insulating layer 200 may be laminated on the upper and lower surfaces of the glass layer 100. Each insulating layer 200 may be laminated as a single layer or in multiple layers.

The insulating layer 200 may be made of a known insulating material. Although not shown, circuit patterns and chips may be defined on an outer surface of the insulating layer 200.

The insulating layer 200 may function as a wiring distribution redistribution layer RDL for electrical connection between a chip and the conductive material 300 filled in the through-hole 110 of the glass layer 100.

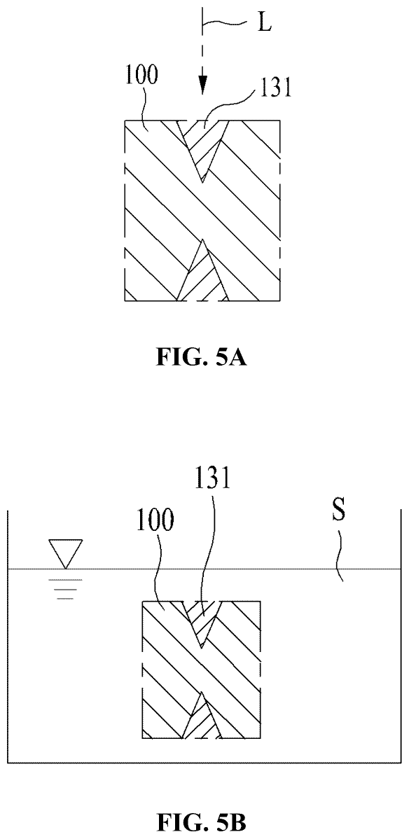

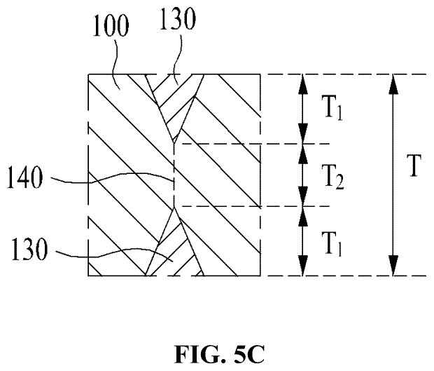

FIGS. 5A, 5B, and 5C are each an exemplary view for explaining a procedure of defining cutting grooves in a glass layer according to an embodiment.

Cutting grooves 130 of a glass layer 100 may be defined by sequentially undergoing a reforming process using a laser beam L and an etching process for immersion in an etching solution S.

Specifically, as shown in FIG. 5A, a laser beam L may be irradiated to the glass layer 100 to define a transformable portion 131 extending in the thickness direction of the glass layer 100. In the transformable portion 131, physical and chemical structural transformation occurs by a nonlinear photo ionization mechanism caused by a laser beam L.

In addition, as shown in FIG. 5B, the glass layer 100 on which the transformable portion 131 is defined is immersed in an etching solution S and the transformable portion 131 is etched and removed, and thus, as shown in FIG. 5C, the cutting grooves 130 may be defined on the upper and lower surfaces of the glass layer 100. The transformable portion 131 may be etched in response to an alkaline or acidic etching solution S 20 to 300 times faster than a non-transformable portion area that is not irradiated with a laser beam L.

Of course, the etching speed of the transformable portion 131 may be adjusted by various variables such as the power of a laser beam, the pulse duration, the repetition rate, the wavelength, the focal length, the scan speed, and the concentration of an etching solution, and accordingly, a depth T1 of the cutting grooves 130, the shape of the cutting grooves 130, and a thickness T2 of an extension portion 140 may be appropriately adjusted.

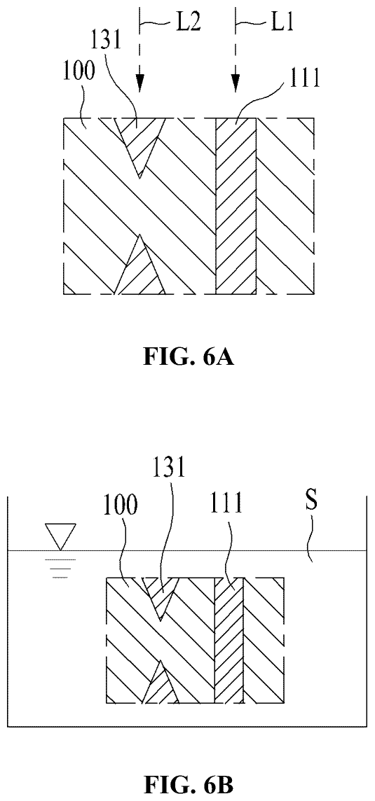

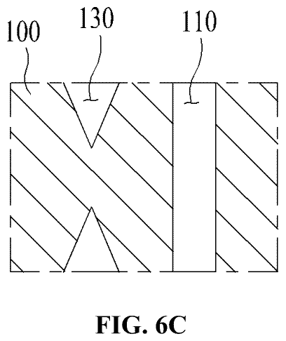

FIGS. 6A, 6B, and 6C are each an exemplary view for explaining a procedure of defining cutting grooves in a glass layer according to another embodiment.

Cutting grooves 130 of a glass layer 100 may be defined together during a procedure of defining a through-hole 110.

That is, the through-hole 110 and the cutting grooves 130 of the glass layer 100 may be defined simultaneously by sequentially undergoing a reforming process using a laser beam L and an etching process for immersion in an etching solution S.

Specifically, as shown in FIG. 6A, a laser beam L may be irradiated to the glass layer 100 to define a first transformable portion 111 and a second transformable portion 131 extending in the thickness direction of the glass layer 100. The first transformable portion 111 is a portion where the through-hole 110 is defined, and the second transformable portion 131 is a portion where the cutting grooves 130 are defined.

In addition, as shown in FIG. 6B, the glass layer 100 on which the first transformable portion 111 and the second transformable portion 131 are defined is immersed in an etching solution S so that the first transformable portion 111 and the second transformable portion 131 are etched and removed. Thus, as shown in FIG. 6C, the through-hole 110 and the cutting grooves 130 may be defined simultaneously in the glass layer 100.

Here, in order to define the through-hole 110 and the cutting groove 130, the power of a first laser beam L1 defining the first transformable portion 111 and the power of a second laser beam L2 defining the second transformable portion 131 may be set differently. That is, the power of the first laser beam L1 is set to be relatively large, and the power of the second laser beam L2 is set to be relatively small, so that the lengths (depths) of the first transformable portion 111 and the second transformable portion 131 may be defined differently.

As another example, in order to define the through-hole 110 and the cutting grooves 130, the focusing position of the first laser beam L1 defining the first transformable portion 111 and the focusing position of the second laser beam L2 defining the second transformable portion 131 may be set differently. For example, when using a Bessel beam as a laser beam, by setting the position of a Bessel beam of the first laser beam L1 to correspond to the length (depth) of the first transformable portion 111 and by setting the position of a Bessel beam of the second laser beam L2 to correspond to the length (depth) of the second transformable portion 131, the lengths (depths) of the first transformable portion 111 and the second transformable portion 131 may be set differently. A Bessel beam, which may be formed using an optical system such as a convex axicon lens, may have a length component of energy intensity that is uniform to a desired length along the thickness direction of the glass layer 100. In addition, the length of a Bessel beam may be changed by changing the angle of an exit surface of a convex axicon lens.

As another example, in order to define the through-hole 110 and the cutting groove 130, the etching time of the first transformable portion 111 and the etching time of the second transformable portion 131 immersed in an etching solution S may be set differently. That is, if the etching time of the first transformable portion 111 is set to be relatively long, the cutting grooves 130 may be defined with a relatively large amount of etching. In addition, if the etching time of the second transformable portion 131 is set to be relatively short, the cutting grooves 130 may be defined with a relatively little amount of etching.

In a specific embodiment, first, the first laser beam L1 is irradiated to the glass layer 100 to correspond to the through-hole 110 to define the first transformable portion 111 extending in the thickness direction of the glass layer 100. Thereafter, the glass layer 100 on which the first transformable portion 111 is defined is immersed in an etching solution S for a first etching time. Then, a portion of the first transformable portion 111, that is, a portion of the through-hole 110, may be etched. Thereafter, the glass layer 100 is separated from the etching solution S, and the second laser beam L2 is irradiated to the glass layer 100 to correspond to the cutting grooves 130 to define the second transformable portion 131 extending in the thickness direction of the glass layer 100. Thereafter, the glass layer 100 on which the second transformable portion 131 is defined is re-immersed in the etching solution S for a second etching time. Then, the remaining portion of the first transformable portion 111 is etched and the second transformable portion 131 is etched at the same time, so that it is possible to define the through-hole 110 and the cutting grooves 130 together.

Likewise, by simultaneously defining the through-hole 110 and the cutting grooves 130 of the glass layer 100, it is possible to quickly prepare the glass layer 100.

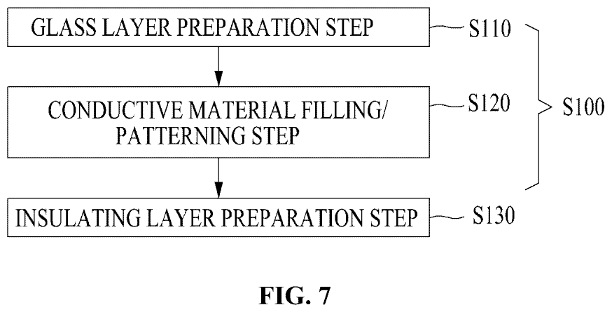

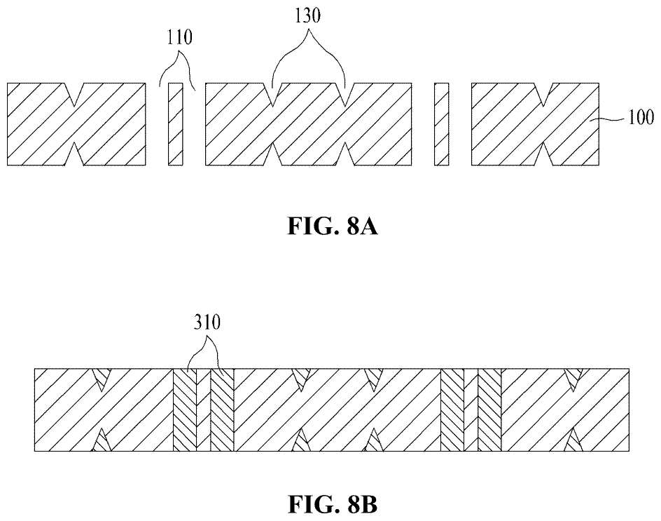

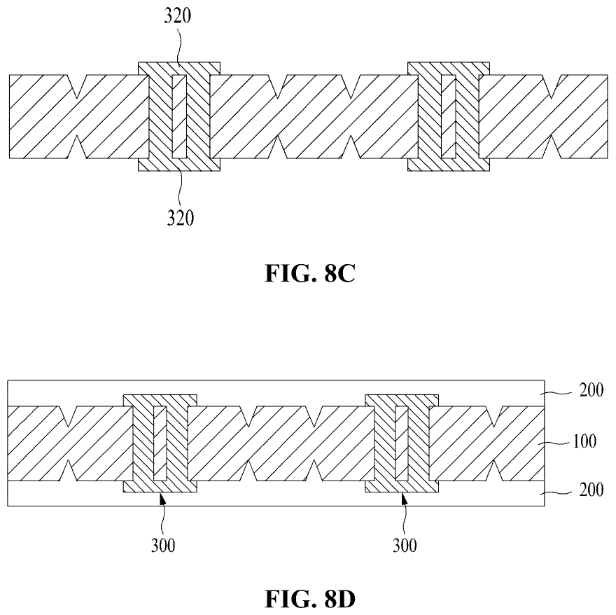

FIG. 7 is a block flow diagram showing a method for manufacturing a glass core laminate according to an embodiment, and FIGS. 8A, 8B, 8C, and 8D are each an exemplary view for showing a method for manufacturing a glass core laminate according to an embodiment.

A method for manufacturing a glass core laminate according to this embodiment may include a glass layer preparation step S110, a conductive material filling/patterning step S120, and an insulating layer preparation step S130.

The glass layer preparation step S110 may defining a through-hole 110 and cutting grooves 130 in a glass layer 100 (see FIG. 8A).

In the glass layer preparation step S110, the cutting grooves 130 of the glass layer 100 may be defined by sequentially undergoing a reforming process using a laser beam L and an etching process for immersion in an etching solution S. That is, the cutting grooves 130 may be defined as a transformable portion 131 extending in the thickness direction of the glass layer 100 is defined by irradiating a laser beam L to the glass layer 100 and as the transformable portion 131 is etched by immersing the glass layer 100 on which the transformable portion 131 is defined in an etching solution S. In this procedure, an extension portion 140 prepared in a space between a pair of transformable portions 131 may be transformed to have strong resistance.

In addition, as described above, the through-hole 110 and the cutting grooves 130 of the glass layer 100 may be defined simultaneously by sequentially undergoing a reforming process using a laser beam L and an etching process for immersion in an etching solution S.

Here, the power of a first laser beam L1 defining a first transformable portion 111 corresponding to the through-hole 110 and the power of a second laser beam L2 defining a second transformable portion 131 corresponding to the cutting grooves 130 may be set differently.

In addition, the focusing position of the first laser beam L1 defining the first transformable portion 111 corresponding to the through-hole 110 and the focusing position of the second laser beam L2 defining the second transformable portion 131 corresponding to the cutting grooves 130 may be set differently.

In addition, the etching time of the first transformable portion 111 corresponding to the through-hole 110 and the etching time of the second transformable portion 131 corresponding to the cutting grooves 130 may be set differently.

In a specific embodiment, first, the first laser beam L1 is irradiated to the glass layer 100 to correspond to the through-hole 110 to define the first transformable portion 111 extending in the thickness direction of the glass layer 100. Thereafter, the glass layer 100 on which the first transformable portion 111 is defined is immersed in an etching solution S for a first etching time. Then, a portion of the first transformable portion 111, that is, a portion of the through-hole 110, may be etched. Thereafter, the glass layer 100 is separated from the etching solution S, and the second laser beam L2 is irradiated to the glass layer 100 to correspond to the cutting grooves 130 to define the second transformable portion 131 extending in the thickness direction of the glass layer 100. Thereafter, the glass layer 100 on which the second transformable portion 131 is defined is re-immersed in the etching solution S for a second etching time. Then, the remaining portion of the first transformable portion 111 is etched and the second transformable portion 131 is etched at the same time, so that it is possible to define the through-hole 110 and the cutting grooves 130 together.

Of course, the through-hole 110 and the cutting grooves 130 may be adjusted by not only the power of a laser beam, the focusing position, and the etching time but also various variables such as the pulse duration of the laser beam, the repetition rate, the wavelength, the focal length, the scan speed, and the concentration of an etching solution, and accordingly, the shape and depth of the through-hole 110 and the cutting grooves 130 may be appropriately adjusted.

The conductive material charging/patterning step S120 may be filling the through-hole 110 with a conductive material 300 and defining patterning on the upper and lower ends of the conductive material 300 exposed to the upper and lower portions of the glass layer 100 for electrical connection with a chip and a circuit pattern coupled to an insulating layer 200. This conductive material filling/patterning step S120 may be omitted depending on a manufacturing process (see FIGS. 8B and 8C).

The insulating layer preparation step S130 may be laminating the insulating layer 200 on the upper and lower surfaces of the glass layer 100 (see FIG. 8D).

The insulating layer 200 may be laminated as a single layer or in multiple layers. In addition, although not shown, defining a circuit pattern and a chip on an outer surface of the insulating layer 200 may be performed after the insulating layer preparation step S130.

Likewise, once the manufacturing of the glass core laminate 10 is completed, a packaging unit is cut and separated via a singulation process.

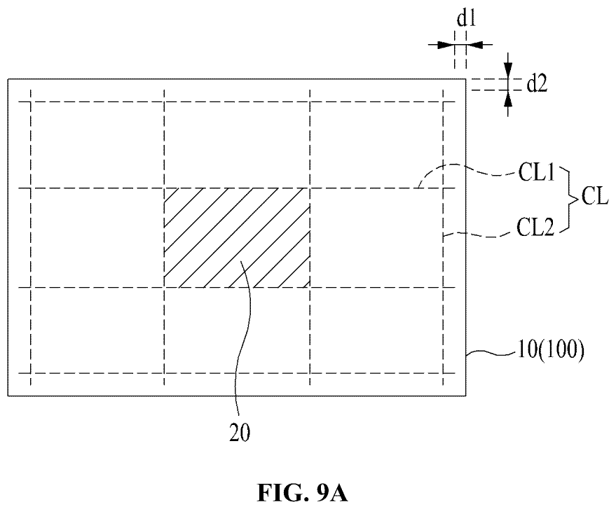

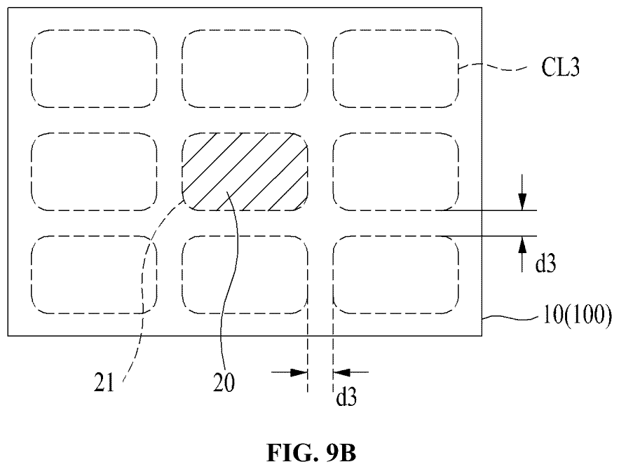

FIGS. 9A and 9B are each a plan view of a glass core laminate for explaining a pattern of a singulation cutting line according to an embodiment.

First, as shown in FIG. 9A, a singulation cutting line CL according to this embodiment may have first cutting lines CL1 and second cutting lines CL2.

The first cutting lines CL1, which are to define a horizontal side of a package unit 20, may extend in the horizontal direction and may be disposed to be spaced apart from each other by the vertical width of the package unit 20.

The second cutting lines CL2, which are to define a vertical side of the package unit 20, may extend in the vertical direction and may be disposed to be spaced apart from each other by the horizontal width of the package unit 20.

In FIG. 9A, when a singulation process is completed through the first cutting lines CL1 and the second cutting lines CL2, nine package units 20 may be obtained from one glass core laminate 10.

In addition, as shown in FIG. 9A, starting and ending points of each of the first cutting lines CL1 and the second cutting lines CL2 may be disposed at a predetermined distance d1 or d2 apart from an edge side surface of a glass layer 100 without extending to the edge side surface of the glass layer 100. As a result, cutting grooves 130 are also defined in a shape corresponding to the first cutting lines CL1 and the second cutting lines CL2.

Likewise, as an end (corresponding to a starting or ending point of a cutting line CL) of the cutting grooves 130 defined to correspond to the cutting line CL is disposed away from an edge side surface without extending to the edge side surface of the glass layer 100, during a singulation process, that is, a procedure of cutting and separating the plurality of package units 20, it is possible to reduce the defect rate due to damage to package units 20 present in a border area.

Meanwhile, as shown in FIG. 9B, a singulation cutting line according to this embodiment may have a plurality of unit cutting lines CL3.

The unit cutting lines CL3 may be prepared to correspond to the shape of package units 20. In addition, the plurality of unit cutting lines CL3 may be disposed to be spaced apart from each other at a predetermined distance d3 in the horizontal and vertical directions of the package units 20.

Likewise, the cutting grooves 130 defined to correspond to the cutting line CL may be not only disposed away from an edge side surface of the glass layer 100, but also maintain a predetermined distance d3 between neighboring package units 20, thereby further reducing the defect rate due to damage during a procedure of cutting and separating the package units 20.

In addition, the unit cutting line CL3 may preferably be defined to have a curved corner area 21. Thus, a following additional corner processing process for the package units 20 may be excluded, and the defect rate due to damage in a corner area during a singulation process may be further reduced.

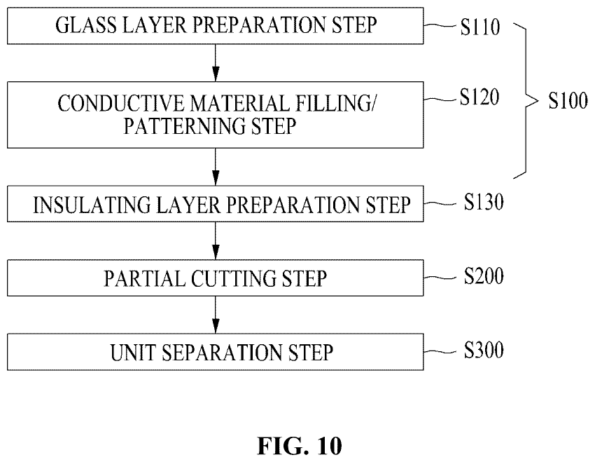

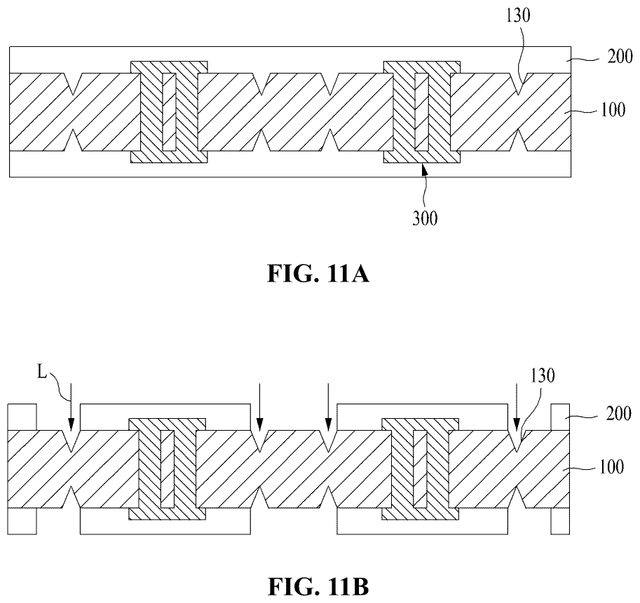

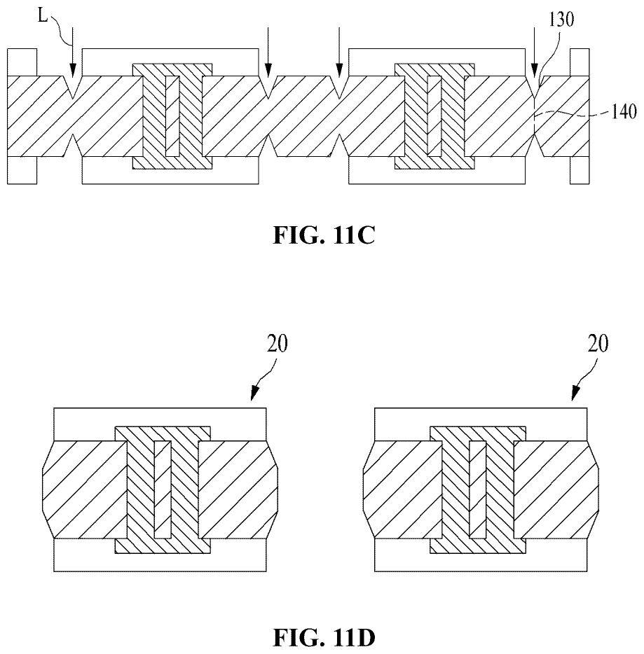

FIG. 10 is a block flow diagram showing a method for cutting a glass core laminate according to an embodiment, and FIGS. 11A, 11B, 11C, and 11D are each an exemplary view showing a method for cutting a glass core laminate according to an embodiment.

A method for cutting a glass core laminate according to this embodiment may include a glass core laminate manufacturing step S100, a partial cutting step S200, and a unit separation step S300.

As described above, the glass core laminate manufacturing step S100 may be manufacturing a glass core laminate 10, and include a glass layer preparation step S110, a conductive material filling/patterning step S120, and an insulating layer preparation step S130. Redundant explanation therefor will be omitted (see FIG. 11A).

The partial cutting step S200 may be removing a portion of an insulating layer 200 by irradiating a laser beam L to the insulating layer 200 so that cutting grooves 130 are exposed on a surface of the glass core laminate 10. The capacity of the insulating layer 200 removed in the partial cutting step S200 is determined to be sufficient if it is possible to expose the cutting grooves 130 on a surface of the glass core laminate 10 (see FIG. 11B).

The unit separation step S300 may be separating a package unit 20 from the glass core laminate 10 by irradiating a laser beam L or applying a physical external force to a glass layer 100 so that an extension portion 140, which is the remaining area of a singulation cutting line CL where the cutting grooves 130 are not defined, is broken in the glass layer 100 (see FIGS. 11C and 11D).

Likewise, since a side cutting area of the package unit 20 cut and separated via a singulation process is prepared by the cutting grooves 130 defined via a laser reforming and etching process for the glass layer 100, it is possible to suppress the occurrence of physical damage such as chipping and cracks regardless of the magnitude of a laser beam or an external physical force used during the singulation process. Accordingly, it is possible to greatly enhance the yield of the package unit 20 and reliability of a product.

In addition, in the case of the extension portion 140 in which the cutting grooves 130 are not defined compared to the cutting grooves 130, a laser beam or external physical force may be directly transmitted during a singulation process. However, since the extension portion 140 may also have strong resistance during a process of defining the cutting grooves 130 of the glass layer 100, that is, a reforming and etching process, it is possible to minimize physical damage such as chipping and cracks during a singulation process.

The above-described method according to the embodiments is depicted with a series of numbered steps for clarity, but the numbering order does not specify the order of each step. That is, some of these steps may be skipped, performed in parallel, or performed without having to strictly maintain a forward/backward order. However, in general, the method proceeds according to the numbered sequence of steps indicated.

The description of the disclosure described above is for illustrative purposes, and those skilled in the art will understand that the disclosure is easily modifiable into other specific forms without changing the technical idea or essential features of the disclosure. Therefore, the embodiments described above should be understood in all respects as illustrative and not restrictive. For example, each component described as single may be implemented in a distributed manner, and similarly, components described as distributed may also be implemented in a combined form.

The scope of the disclosure is indicated by the claims described below, and all changes or modified forms derived from the meaning and scope of the claims and their equivalent concepts should be construed as being included in the scope of the disclosure.

### Explanation of Reference Numerals

10: Glass core laminate
20: Package unit
100: Glass layer
110: Through-hole
130: Cutting groove
200: Insulating layer
300: Conductive material

What is claimed is:

1. A glass core laminate, comprising:
a glass layer; and
an insulating layer laminated on upper and lower surfaces of the glass layer,
wherein the glass layer has cutting grooves defined in advance along a singulation cutting line before the insulating layer is laminated on the upper and lower surfaces.

2. The glass core laminate of claim 1, wherein the cutting grooves are defined as a transformable portion extending in a thickness direction of the glass layer is defined by irradiating a laser beam to the glass layer and as the transformable portion is etched by immersing the glass layer on which the transformable portion is defined in an etching solution.

3. The glass core laminate of claim 1, wherein:
the glass layer further has a through-hole for electrical connection between layers of the glass core laminate;
the through-hole is defined as a transformable portion extending in a thickness direction of the glass layer is defined by irradiating a laser beam to the glass layer and as the transformable portion is etched by immersing the glass layer on which the transformable portion is defined in an etching solution; and
the cutting grooves are defined together when the through-hole is defined.

4. The glass core laminate of claim 3, wherein the through-hole and the cutting grooves are defined together as at least one of the followings is set differently:
power of the laser beam for defining the through-hole and the cutting grooves, respectively;
a focusing position of the laser beam for defining the through-hole and the cutting grooves, respectively; and
an etching time for defining the through-hole and the cutting grooves, respectively.

5. The glass core laminate of claim 1, wherein the singulation cutting line comprises:
a plurality of first cutting lines that, to define a horizontal side of a package unit, extend in a horizontal direction and are spaced apart by a vertical width of the package unit; and
a plurality of second cutting lines that, to define a vertical side of the package unit, extend in a vertical direction and are spaced apart by a horizontal width of the package unit,
wherein starting and ending points of each of the first cutting lines and the second cutting lines are disposed away from an edge side surface of the glass layer without extending to the edge side surface of the glass layer.

6. The glass core laminate of claim 1, wherein the singulation cutting line comprises a plurality of unit cutting lines prepared to correspond to a shape of a package unit and spaced apart at predetermined intervals in the horizontal and vertical directions of the package unit.

7. The glass core laminate of claim 6, wherein the unit cutting lines have a curved corner area.

8. A method for manufacturing a glass core laminate, the method comprising:
a glass layer preparation step of preparing a glass layer; and
an insulating layer preparation step of laminating an insulating layer on upper and lower surfaces of the glass layer,
wherein in the glass layer preparation step, the glass layer has cutting grooves defined along a singulation cutting line on the upper and lower surfaces.

9. The method of claim 8, wherein in the glass layer preparation step, the cutting grooves are defined as a transformable portion extending in a thickness direction of the glass layer is defined by irradiating a laser beam to the glass layer and as the transformable portion is etched by immersing the glass layer on which the transformable portion is defined in an etching solution.

10. The method of claim 8, wherein:
in the glass layer preparation step, the glass layer further has a through-hole for electrical connection between layers of the glass core laminate;
the through-hole is defined as a transformable portion extending in a thickness direction of the glass layer is defined by irradiating a laser beam to the glass layer and as the transformable portion is etched by immersing the glass layer on which the transformable portion is defined in an etching solution; and
the cutting grooves are defined together when the through-hole is defined.

11. The method of claim 10, wherein in the glass layer preparation step, the through-hole and the cutting grooves are defined together as at least one of the followings is set differently:
power of the laser beam for defining the through-hole and the cutting grooves, respectively;
a focusing position of the laser beam for defining the through-hole and the cutting grooves, respectively; and
an etching time for defining the through-hole and the cutting grooves, respectively.

12. The method of claim 11, wherein the power of the laser beam irradiated to define the cutting grooves are smaller than the power of the laser beam irradiated to define the through-hole.

13. The method of claim 10, wherein in the glass layer preparation step, the through-hole and the cutting grooves are defined together by:
defining a first transformable portion extending in the thickness direction of the glass layer by irradiating a first laser beam to the glass layer;
etching a portion of the first transformable portion by immersing the glass layer on which the first transformable portion is defined in an etching solution for a first etching time;
separating the glass layer from the etching solution, and irradiating the glass layer with a second laser beam to define a second transformable portion extending in the thickness direction of the glass layer; and
immersing the glass layer on which the second transformable portion is defined in an etching solution for a second etching time to etch a remaining portion of the first transformable portion and simultaneously etch the second transformable portion.

14. The method of claim 10, further comprising, prior to the insulating layer preparation step, a conductive material filling and patterning step of filling and patterning the through-hole with a conductive material.

15. A method for cutting a glass core laminate, the method comprising:
a laminate manufacturing step of manufacturing the glass core laminate according to claim 8;
a partial cutting step of removing a portion of an insulating layer by irradiating a laser beam to the insulating layer so that cutting grooves are exposed on a surface of the glass core laminate; and
a unit separation step of separating a package unit from the glass core laminate by irradiating a laser beam or applying a physical external force to a glass layer so that a remaining area of a singulation cutting line where the cutting grooves are not defined is broken.
